(19) United States
(12) Patent Application Publication
(10) Pub. No.: US 2021/0013357 A1
(43) Pub. Date: Jan. 14, 2021

(54) Photodiode

(71) Applicants: University College Cardiff Consultants Limited, Cardiff (GB); The Regents of The University of California, Oakland, CA (US); University of Sheffield, Sheffield (GB)

(72) Inventors: Baolai Liang, Los Angeles, CA (US); Shiyu Xie, Cardiff (GB); Diana Lynne Huffaker, Cardiff (GB); John Paul Raj DAVID, Sheffield (GB); Chee Hing Tan, Sheffield (GB)

(73) Assignees: University College Cardiff Consultants Limited, Cardiff (GB); The Regents of The University of California, Oakland, CA (US); University of Sheffield, Sheffield (GB)

(21) Appl. No.: 16/504,724

(22) Filed: Jul. 8, 2019

(51) Int. Cl. H01L 31/107; H01L 31/0216; H01L 31/0304; H01L 31/0352; H01L 31/18

(52) U.S. Cl. CPC H01L 31/1075; H01L 31/02161; H01L 31/1868; H01L 31/035281; H01L 31/1844; H01L 31/03046

(57) ABSTRACT

In an example, an avalanche photodiode comprises a substrate and a structure comprising a first layer and a second layer, the first and second layers over and parallel to the substrate, wherein the first layer is between the substrate and the second layer. The first layer is an Aluminium Arsenide Antimonide multiplication layer, and wherein the cross-sectional area parallel to the substrate of the first layer is smaller than that of the second layer, thereby forming a recess in a sidewall of the structure.

### BACKGROUND

Avalanche photodiodes are semiconductor-based devices that act as photodetectors, converting light to electricity, with a built-in first stage of gain which increases the sensitivity over other types of semiconductor photodiodes. In operation, a reverse voltage may be applied to an avalanche photodiode and, generally, the higher the reverse voltage applied, the higher the gain.

Avalanche photodiodes have conventionally been fabricated with a multiplication region (which provides the gain) comprising silicon, however other materials such as Germanium, Gallium Nitride (GaN) or Indium Phosphide (InP) have also been used. The material used can influence the wavelength of radiation to which the avalanche photodiode is sensitive. For example silicon may be used for avalanche photodiodes to detect visible and near infrared radiation and GaN may be used for photodiodes to detect ultraviolet radiation. The thickness of the avalanche layer affects the ratio of ionization coefficients. It may be noted that in silicon, the electron ionization coefficient is much larger than the hole ionization coefficient at low electric fields.

Avalanche photodiodes are manufactured by growing or depositing materials on a substrate. Semiconductor processing techniques such as photolithography and electron beam lithography, large scale nano-imprint, electron beam and sputterer metal deposition, inductively coupled plasma etching, reactive ion etching, focused ion beam milling, rapid thermal annealing, dielectric deposition (Plasma-enhanced chemical vapor deposition (PECVD), Atomic layer deposition (ALD), evaporation) may be used to form the structure of the avalanche photodiode.

Avalanche photodiodes have many applications, for example in free-space optics (FSO), fibre-optic communications, laser rangefinders based on Light Detection and Ranging (LIDAR) and other sensing applications. In optical communications such as FSO or fibre-optic communications, an avalanche photodiode may act as an optical receiver. Avalanche photodiodes are particularly effective for use in such communications due to their 5-10 dB higher sensitivity relative to conventional photodetectors without internal gain. Many existing photodiodes for use in such applications operate at wavelengths of 1.3 μm or 1.55 μm.

Examples of known avalanche photodiodes are grown on InP substrates and use InP or InAlAs as the avalanche gain medium, or multiplication layer. However InP and InAlAs have higher noise performance and lower sensitivity compared to silicon avalanche photodiodes. Other avalanche photodiodes exist which have a better noise performance, such as InAs and AlInAsSb, however they are grown on a more expensive and low resistivity InAs or GaSb substrate.

FIG. 1A shows a cross-section of a prior art ‘bottom illuminated’ avalanche photodiode, wherein bottom illuminated means the photodiode is sensitive to illumination from below the substrate. The avalanche photodiode comprises a multiplication layer 108 of InAlAs. The photodiode comprises a layered structure with the following layers, in order from the top of the structure: n-type contact 102, grading field buffer 104, n-type electric charge layer 106, multiplication layer 108, p-type field control layer 110, undoped InGaAs absorption layer 112, p-type InGaAs absorption layer 114, p-type contact 116, InP substrate 118 and anti-reflective coating 120. The structure is stepped with layers with relatively small cross-sectional area at the top of the structure and layers with relatively large cross-sectional area at the bottom of the structure. The structure is ‘inverted’ relative to ‘top illuminated’ photodiodes, with the N-type contact layer at the top of the device structure. This results in the p-type material being at the bottom of the structure and therefore a wide-bandgap p-type InP based alloy is used for the p-type contact layer to allow lattice matching with an InP substrate. However this may increase difficulty in producing the ohmic contact and increase resistance. Additionally there is little field confinement in the p-type absorption layer (e.g. layer 114) so the parasitic capacitance may be relatively large.

FIG. 1B shows a cross-section of a second prior art avalanche photodiode. The device is a ‘top illuminated’ photodiode and comprises a tapered structure in which the upper layers have a smaller cross-sectional area than the lower layers. The photodiode comprises a layered structure with the following layers, in order from the top of the structure: p-type GaSb contact 150, AlInAsSb absorption layer 152, AlInAsSb multiplication layer 154, GaSb n-type contact layer 156 and GaSb substrate 158. The structure further comprises sidewall passivation 160 and ohmic contacts 162.

### SUMMARY OF INVENTION

According to a first aspect of the invention, there is provided an avalanche photodiode comprising a substrate and a structure. The structure comprises a first layer and a second layer, the first and second layers being arranged over and parallel to the substrate, wherein the first layer is between the substrate and the second layer (and in some examples is in contact with the substrate and/or the second layer). The first layer is an Aluminium Arsenide Antimonide (AlAsSb) multiplication layer, and the cross-sectional area parallel to the substrate of the first layer is smaller than that of the second layer, such that there is a recess in a sidewall of the structure. The relatively small cross-sectional area of AlAsSb layer provides confinement of the electric field. Furthermore, in use, dark current (which is proportional to the cross-sectional area of the layer) is reduced because of the reduced cross-sectional area of the AlAsSb layer. AlAsSb can also provide improved performance over silicon based avalanche photodiodes, with significantly reduced noise. Additionally silicon is unable to detect radiation at visible wavelengths, whereas AlAsSb (for example, when provided within a structure including an absorption layer such as an InGaAs absorption layer), is capable of detecting visible light.

In some examples the structure comprises “steep-sided” sidewall(s) above the recess, wherein the sidewall(s) may be steep-sided in that their angle is closer to vertical than to the plane of the substrate, and in some examples the sidewalls may be near vertical (e.g. up to around 10° from vertical, or up to around 5° from vertical) or vertical. As used herein ‘vertical’ is used to mean perpendicular relative to the substrate. Such steep-sided (in some examples, vertical or near vertical) sidewalls may be defined using photolithography and formed using conventional semiconductor processing techniques such as plasma etching.

In some examples the steep-sided sidewall(s) of the structure and the recess are coated with a dielectric material. Such layers are known as passivation layers and can include materials such as Al₂O₃, SiO₂, SiNₓ, benzocyclobutene (BCB) and SU-8. Passivation layers such as Al₂O₃ may be deposited by atomic layer deposition. The passivation layer may improve mechanical stability of the structure, preserve the surface states leading to improved reliability of the photodiode, and/or reduce leakage currents.

In some examples the avalanche photodiode has maximum responsivity at a wavelength of 1.3 μm or 1.55 μm. These wavelengths are typically used in existing optical networks, so providing an avalanche photodiode with high responsivity at these wavelengths allows compatibility with existing infrastructure. The device structure and materials may be selected to ensure responsivity at these wavelengths, for example a PIPIN structure (described in greater detail below) allows such operation.

In some examples the thickness of the first layer is 0.6 μm to 1.5 μm. The thickness of the first layer contributes towards determining the operational properties of the avalanche photodiode. Such a relatively thick AlAsSb layer provides improved performance relative to silicon based photodiodes.

In some examples the structure is a PI PIN structure. A PIPIN structure allows use of materials which can absorb radiation with wavelengths of 1.3 μm and 1.55 μm which allows for interoperability with existing infrastructure, for example with existing telecom infrastructure.

In some examples the PIPIN structure comprises layers, in the following order: a P-type contact layer at the top of the structure; an intrinsic absorption layer; an intrinsic grading layer; a P-type charge layer; the first layer; and an N-type contact layer, adjacent to the substrate. The second layer is at least one of the P-type contact layer, the intrinsic absorption layer, the intrinsic grading layer or the P-type charge layer.

In some examples the avalanche photodiode is a top illuminated photodiode. When the avalanche photodiode is top illuminated, the entire backside of the substrate may form a contact, which is therefore easier to align as no backside patterning is required. A top illuminated avalanche photodiode may have a reduced cost of manufacture relative to a bottom illuminated avalanche photodiode due to this ease of alignment.

In some examples the avalanche photodiode further comprises at least one of a top and bottom contact. In some examples there may be a top contact and no bottom contact. A bottom contact may be mounted on the substrate and a top contact may be mounted on a layer distal to the substrate.

In some examples the first layer is lattice matched to the substrate, which may be an Indium Phosphide (InP) substrate. Lattice matching when growing a layer of semiconductor with different bandgap on InP avoids introducing a change in the crystal structure. If an avalanche photodiode was constructed without lattice matching, then there could be strain and/or defects at the interface and the resulting device performance may be compromised.

In some examples the first layer is an AlAs_{0.56}Sb_{0.44} layer. AlAs_{0.56}Sb_{0.44} provides has a relatively large indirect band-gap of around 1.65 eV and is lattice matched to InP.

In some examples the second layer comprises an InGaAs absorption layer, which may be lattice matched to the substrate.

According to a second aspect of the invention there is provided a method of fabricating an avalanche photodiode. The method comprises depositing a first layer comprising Aluminium Arsenide Antimonide over a substrate; depositing a second layer over the first layer; and removing a portion of the first layer so that the first layer has a smaller cross-sectional area than the second layer in a plane parallel to the substrate. Removing a portion of the first layer reduces the dark current because dark current is proportional to the cross-sectional area. Furthermore the relatively wide second layer provides for easier alignment and manufacture because any features which are to be defined on top of the structure have a larger target area. Furthermore resistance is inversely proportional to the cross-sectional area, so the resistance of the wider second layer is reduced by its relatively large cross-sectional area.

AlAsSb layers have been suggested for use in laser devices. However due to the relatively small thickness of such a layer in a laser device, the process would be difficult to control and the conditions required for the process may not be commercially viable due to the high temperature (500° C.) and long processing time required.

In some examples removing a portion of the first layer comprises performing a wet oxidation process on the first and second layers. AlAsSb has a relatively high oxidation rate. Therefore it will oxidise to a greater extent than the other layers forming a thicker oxide. The oxidation process thereby causes a reduction in the cross-sectional area of the first layer.

In some examples removing a portion of the first layer further comprises removing the oxide formed by the wet oxidation process. Removing the oxide forms a recess in the first layer, so that the second layer overhangs the first layer, providing the above advantages.

In some examples, prior to removing a portion of the first layer, an etch process is performed on the first layer and the second layer to form a structure comprising the first layer and the second layer with (at least substantially, or nearly) vertical sidewalls.

In some examples a dielectric material is deposited on the sides of the first layer and second layer. The dielectric material acts as a passivation layer, provides additional mechanical support to the structure and/or can also improve the electrical properties of the photodiode for example by reducing leakage currents and improving reliability.

In some examples the first layer is deposited using a digital alloy process. Digital alloy deposition comprises sequentially depositing alternating thin layers of the metals of the alloy. This allows precise lattice-matched alloys to be grown with high crystalline quality.

### BRIEF DESCRIPTION OF THE FIGURES

Non-limiting examples will now be described with reference to the accompanying drawings, in which:

FIGS. 1A and 1B show cross-sections of prior art avalanche photodiodes;

FIG. 2A shows an avalanche photodiode according to one embodiment of the invention;

FIG. 2B shows a cross-section of an avalanche photodiode along the line X-X of FIG. 2A;

FIG. 3 is a flowchart of an example method of fabricating an avalanche photodiode;

FIG. 4 is a flowchart of a further example method of fabricating an avalanche photodiode; and

FIGS. 5A to 5E show cross-sections of an avalanche photodiode at sequential stages of manufacture.

### DETAILED DESCRIPTION

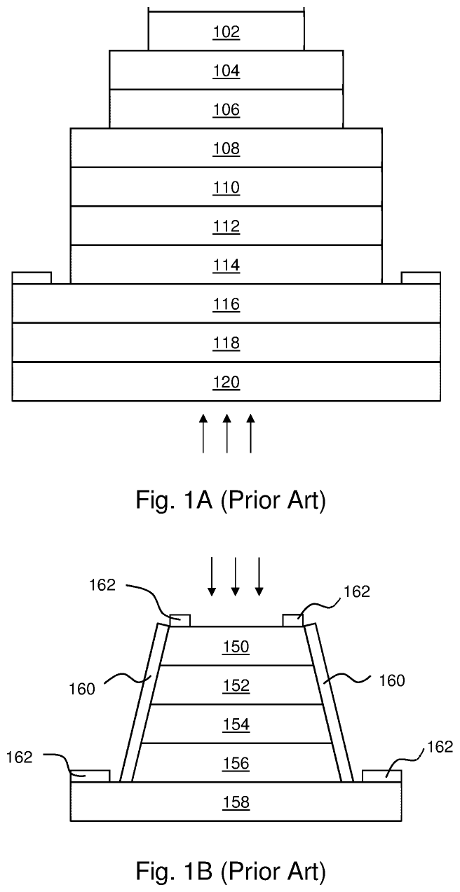

FIGS. 1A and 1B have discussed above.

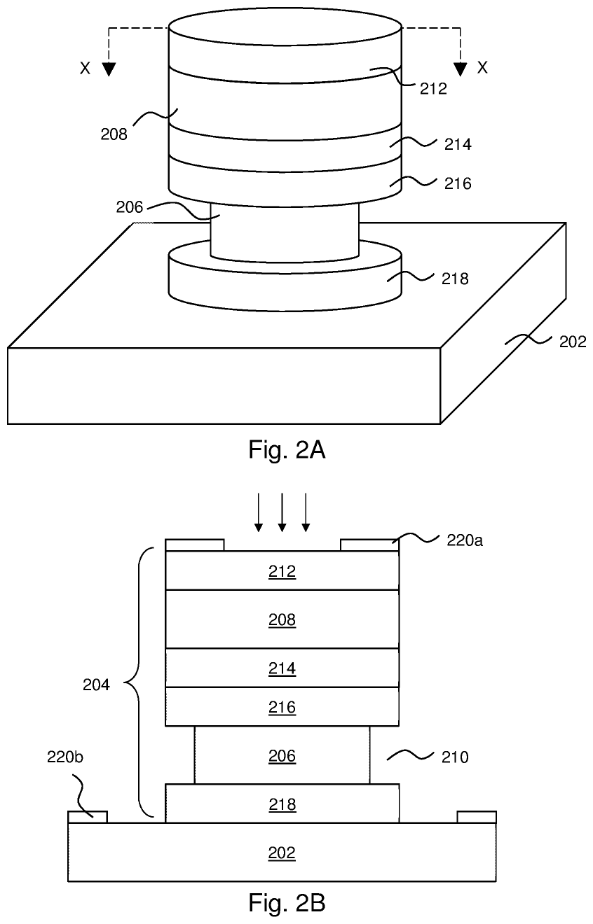

FIG. 2A and FIG. 2B show an avalanche photodiode comprising a substrate 202 and a structure 204. The structure 204 is raised above the surface of the substrate 202, and such structures may be referred to as mesa structures (a structure which is raised above the surrounding substrate). FIG. 2B is a cross-section along the line X-X of FIG. 2A, additionally showing metal contacts.

The structure 204 comprises a first layer 206 and a second layer 208, both of which are over and parallel to a major plane of the substrate 202. The first layer 206 is arranged between the substrate 202 and the second layer 208.

The first layer 206 is an Aluminium Arsenide Antimonide (AlAsSb) multiplication layer, also known as an avalanche layer. AlAsSb may be lattice matched to substrates such as InP substrates. AlAsSb also has high temperature stability compared with some other semiconductor materials such as InAlAs, InP or GaAs.

The cross-sectional area parallel to the substrate 202 of the first layer 206 is smaller than that of the second layer 208, thereby forming a recess 210 in a sidewall of the structure 204. The recess may be at least 5 μm deep, and can be up to tens of microns deep. The relatively small cross-section of the first layer 206 provides a reduction in size of the high field area but without influencing the absorption or contact layers, which are described in greater detail below. The first layer may have a reduced width, wherein the width may measure from 10 μm up to hundreds of microns. This results in reduced dark current relative to a first layer 206 with a larger cross-sectional area because dark current is proportional to the cross-sectional area. Such photodiodes may have a low excess noise factor of ˜2 and may have a bandwidth of around ≥7 Ghz at an avalanche gain of 50, and so would be capable of operating in 2.5 Gps and 10 Gps FSO links. Examples of the formation of the recess in the first layer 206 are described in more detail below.

FIGS. 2A and 2B also show additional layers of the structure. In the illustrated embodiment, the layers are, in order: a P-type contact layer 212 at the top of the structure, the second layer 208 which is an intrinsic absorption layer, an intrinsic grading layer 214, a P-type charge layer 216, the first layer 206, and an N-type contact layer 218 adjacent to the substrate 202. (In other embodiments, the P-type contact layer 212, the intrinsic grading layer 214, or the P-type charge layer 216 is considered to be the “second” layer.) In this example, the first layer 206 is an intrinsic multiplication layer, for example, an unintentional doped multiplication layer. As can be seen from the figures, in this example, it is only the first layer 206 which has a reduced cross-sectional area. This structure is a PIPIN structure as it comprises layers of p-type (P), intrinsic (I), p-type (P), intrinsic (I) and n-type (N) semiconductor material in that order. Conventional avalanche photodiode in contrast typically have PIN (p-type, intrinsic, n-type) or NIP (n-type, intrinsic, p-type) structure.

The first layer 206 is a multiplication layer and may have a thickness in the range from 0.6 μm to 1.5 μm to provide the bulk property. A thicker first layer 206 provides lower noise, however a thinner first layer 206 provides increased speed of operation. Therefore the thickness of the layer may vary depending on the intended application of the avalanche photodiode to balance the noise and speed requirements for that application. For example, high speed telecommunications, such as 5G, call for high speed operation so a thickness of 0.6 μm may be preferred whereas for applications such as LIDAR, low noise is highly desirable and lower speed of operation may be acceptable so a larger thickness of 1.5 μm may be preferred. The second layer 208 is an intrinsic absorption layer and may have a thickness up to 2 μm, the intrinsic grading layer 214 may have a thickness in the range from 0.1 μm to 0.2 μm, and the P-type charge layer 216 may have a thickness in the range from 0.1 μm to 0.2 μm.

The second layer 208 is the absorption layer and comprises InGaAs lattice matched to the substrate. The intrinsic grading layer 214 may comprise AlGaAs and the P-type charge layer 216 may comprise InAlAs.

As shown in FIG. 2A, the structure has a generally cylindrical shape, however in other examples the structure may have other shapes. Such a shape may be formed by conventional semiconductor processing methods, for example photolithography and wet chemical etching or dry ion etching to form the vertical sidewall(s) above the recess, noting that a cylinder may be considered to have a single sidewall above the recess, whereas other shapes maybe considered to have multiple sidewalls. The cylinder may have a diameter in the range 70 μm to 420 μm, for example around or between 70 μm, 120 μm, 220 μm or 420 μm.

FIG. 2B shows, in addition to layers shown in FIG. 2A, metal contacts 220a, 220b. First contacts 220a are formed on top of the structure and second contacts 220b are formed on the substrate 202. Such contacts may be formed by depositing standard metal ohmic contacts and performing optical photolithography and wet chemical etching. The first contacts 220a have an opening to allow light to enter the photodiode. The relatively wide top of the structure provides a larger area for forming contacts which increases ease of manufacture. The metal contacts 220a, 220b can be formed from metals such as Ti—Au.

The thickness of each layer is selected to achieve a photodiode which operates efficiently at preferred wavelengths. In one example the thickness of the first layer is 1500 nm and the thickness of the second layer is 1000 nm. Responsivity is a measure of the input-output gain of a photodiode, in particular a measure of the electrical output per optical input. Preferably a photodiode will have maximum responsivity at a wavelength at which it is designed to operate. Many existing optical systems operate with wavelengths of 1.3 μm or 1.55 μm. Therefore in some example embodiments, the avalanche photodiode may have a maximum responsivity at a wavelength of 1.3 μm or 1.55 μm.

The avalanche photodiode is a top illuminated photodiode. This means that the photodiode is sensitive to optical radiation entering the top of the structure i.e. the surface of the structure furthest from the substrate. Such a photodiode may comprise second contacts 220b on the upper surface of the substrate 202 as shown in FIG. 2B. Contacts on the upper surface are simpler to align with other features of the photodiode compared with patterning contacts on the backside of a photodiode. In some examples, the second contact or electrode may be formed on the entire backside of the substrate 202 (not shown), which is also relatively easy to manufacture as no patterning is required. In contrast if the photodiode was bottom illuminated such a bottom contact would not be possible.

In the avalanche photodiode, the first layer 206 comprises AlAsSb. In particular, in this example the AlAsSb layer is AlAs_{0.56}Sb_{0.44}, which is lattice matched to the substrate 202 which is an Indium Phosphide (InP) substrate. AlAs_{0.56}Sb_{0.44} provides low tunnelling current with a thin avalanche region width of 80 nm and has a relatively large indirect band gap of ˜1.65 eV. Furthermore it has a relatively high temperature stability. Therefore use of AlAs_{0.56}Sb_{0.44}, provides a photodiode with very low excess noise.

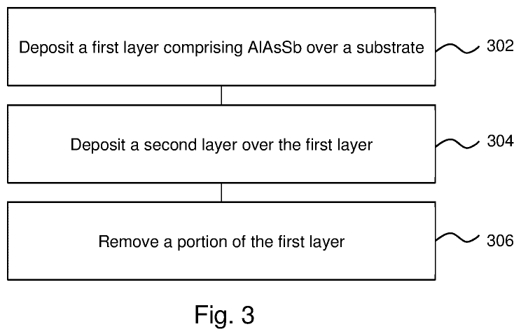

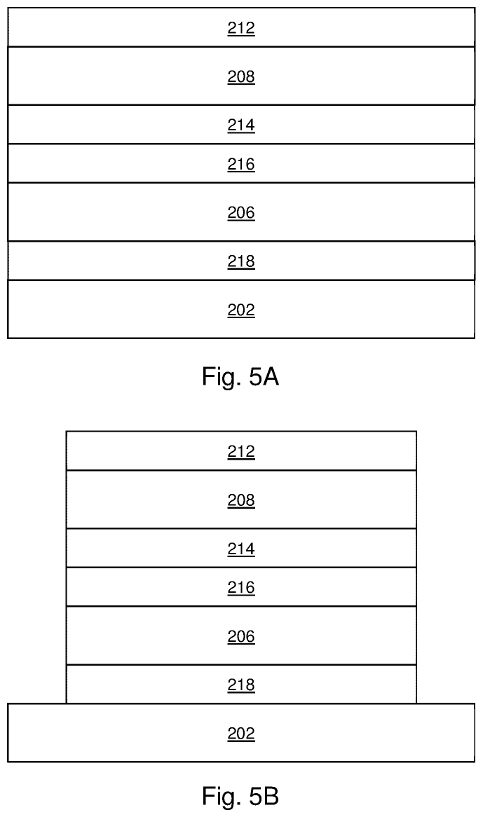

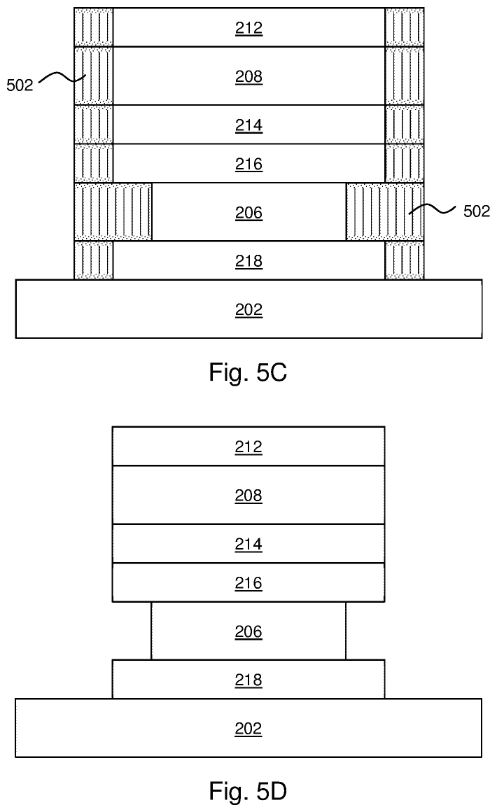

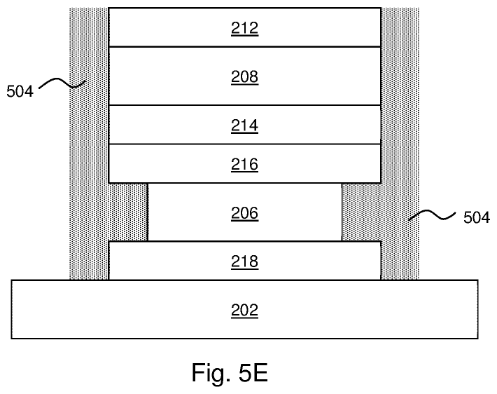

FIG. 3 shows a method of fabricating an avalanche photodiode. In block 302, a first layer comprising Aluminium Arsenide Antimonide is deposited over a substrate. In block 304, a second layer is deposited over the first layer. In block 306, a portion of the first layer is removed so that the first layer has a smaller cross-sectional area than the second layer in a plane parallel to the substrate, for example as is described in greater detail in relation to FIGS. 5A-E below.

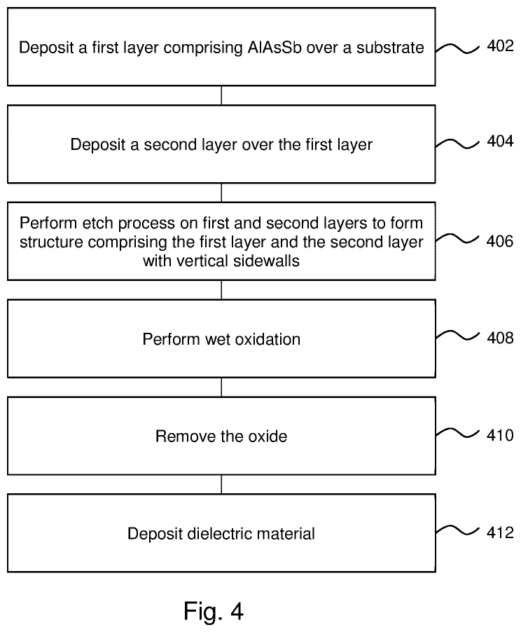

FIG. 4 shows a further example of a method of fabricating an avalanche photodiode. In block 402, a first layer comprising Aluminium Arsenide Antimonide is deposited over a substrate. In block 404, a second layer is deposited over the first layer. In block 406, an etch process is performed on the first and second layers to form a structure comprising the first layer and the second layer with (substantially, or nearly) vertical sidewall(s). In block 408, a wet oxidation process is performed on the first and second layers. In block 410, the oxide formed by the wet oxidation process is removed. Additionally, as a result of blocks 408 and 410, the above-mentioned recess is formed. In block 412 a dielectric material is deposited on the sides of the first layer and the second layer.

The above methods are described with greater detail with respect to FIGS. 5A to 5E.

FIG. 5A shows the layers of the avalanche photodiode deposited on the substrate 202. The layers are deposited over and substantially parallel to the substrate 202 according to blocks 302, 402 and 304, 404 of FIGS. 3 and 4. The first layer 206 may be deposited using a digital alloy process. An example of such a digital alloy is a digital alloy growth technique comprising depositing material in a molecular beam epitaxy reactor, for example, a Veeco GEN930™ MBE reactor, in which both As₂ and Sb₂ fluxes are controlled by using valved cracker cells. In order to achieve a precise lattice-matched AlAsSb alloy with high crystalline quality, digitally grown AlAsSb is realized by periodically alternating the As and Sb shutter to obtain the desired alloy composition, thereby providing lattice-matched AlAsSb on the InP substrate 202. An example of a digital alloy growth technique is described in published US patent application 2017/0244002, which is incorporated herein by reference to the fullest extent permitted as if fully set forth herein.

FIG. 5B shows the substrate 202 and layers after the etch process of block 406 of FIG. 4 has been performed. The layers are patterned, for example using photolithography, then etched, using for example a wet chemical etch or a dry ion or plasma etch, to form a structure with substantially vertical sidewall(s). An example of such a wet chemical etch process uses a 2:1 mixture of citric acid (1 g citric acid powder to 1 ml of de-ionised water) and hydrogen peroxide (H₂O₂) for the removal of InGaAs cap layers and a 1:2:10 mixture of hydrochloric acid, diluted H₂O₂ (with a ratio of 1 part peroxide to 9 parts de-ionised water) and de-ionised water to etch AlAsSb layers.

FIG. 5C shows the substrate 202 and layers after the wet oxidation process of block 408 of FIG. 4 has been performed. Such a wet oxidation process may comprise exposing the substrate 202 and the layers to a temperature up to 300° C. in a tube furnace for several hours and bubbling N₂ or O₂ through water heated to up to approximately 80° C. An oxide 502 forms on the sidewall(s) of the structure. The AlAsSb first layer 206 oxidises at a relatively high rate and therefore a greater thickness of oxide is formed in this layer. This causes a reduction in cross-section of this layer relative to the other layers in the structure.

FIG. 5D shows the substrate 202 after the oxide 502 has been stripped as described in block 410 of FIG. 4. The oxides formed may include for example Al₂O₃ and/or AlO(OH) and can be removed using an acid based etchant. This results in a recess, or undercut, in the first layer 206, which now has a reduced cross-sectional area relative to the other layers. The recess may be present around at least part, and in some examples substantially the whole of the circumference of the first layer 206. Such a recess would be difficult to manufacture in other devices such as lasers, due to the relatively small thickness of about 100 nm of the first layer in such devices. This small thickness would result in a process which would be impractical and difficult to control.

FIG. 5E shows the substrate 202 and layers 206, 208 and 212-218 after a layer of dielectric material 504 has been deposited according to block 412 of FIG. 4. The dielectric material 504 acts as a passivation layer and can be formed of a material such as Al₂O₃, SiO₂, SiNₓ, benzocyclobutene (BCB) or SU-8. The dielectric, or passivation, layer 504 improves the mechanical stability of the structure and/or can also improve the electrical properties of the photodiode for example by reducing leakage currents and improving reliability. In particular Al₂O₃ passivation layers may suppress surface recombination by 2-3 orders of magnitude, and may therefore be preferred. Such Al₂O₃ passivation layers may be thermally deposited at 200° C. at a slow rate of ˜1.1 Å/s to conformal coat etched surfaces.

After formation of the structure shown in FIG. 5E, the metal contacts 220a, 220b can be deposited. The contacts 220a, 220b may comprise metals such as Ti and/or Au.

While the method, apparatus and related aspects have been described with reference to certain examples, various modifications, changes, omissions, and substitutions can be made without departing from the spirit of the present disclosure. It is intended, therefore, that the method, apparatus and related aspects be limited only by the scope of the following claims and their equivalents. It should be noted that the above-mentioned examples illustrate rather than limit what is described herein, and that those skilled in the art will be able to design many alternative implementations without departing from the scope of the appended claims. Features described in relation to one example may be combined with features of another example.

The word “comprising” does not exclude the presence of elements other than those listed in a claim, “a” or “an” does not exclude a plurality, and features of the dependent claims may be combined in any practical combination.

1. An avalanche photodiode comprising:
a substrate; and
a structure comprising a first layer and a second layer, the first and second layers over and parallel to the substrate,
wherein the first layer is between the substrate and the second layer,
wherein the first layer is an Aluminium Arsenide Antimonide multiplication layer, and
wherein a cross-sectional area parallel to the substrate of the first layer is smaller than that of the second layer, thereby forming a recess in a sidewall of the structure.

2. An avalanche photodiode according to claim 1 wherein the sidewall of the structure is vertical or near vertical above the recess.

3. An avalanche photodiode according to claim 2 wherein the sidewall of the structure and the recess are coated with a dielectric material.

4. An avalanche photodiode according to claim 1 wherein the avalanche photodiode has a maximum responsivity at a wavelength of 1.3 μm or 1.55 μm.

5. An avalanche photodiode according to claim 1 wherein a thickness of the first layer is 0.6 μm to 1.5 μm.

6. An avalanche photodiode according to claim 1 wherein the structure is a PIPIN structure.

7. An avalanche photodiode according to claim 6 wherein the PIPIN structure comprises layers, in order:
a P-type contact layer at a top of the structure;
an intrinsic absorption layer;
an intrinsic grading layer;
a P-type charge layer;
the first layer; and
an N-type contact layer, adjacent to the substrate,
wherein the second layer is at least one of the P-type contact layer, the intrinsic absorption layer, the intrinsic grading layer or the P-type charge layer.

8. An avalanche photodiode according to claim 1 wherein the avalanche photodiode is a top illuminated photodiode.

9. An avalanche photodiode according to claim 1 further comprising at least one of:
a top contact mounted on a layer distal to the substrate; or
a bottom contact mounted on the substrate.

10. An avalanche photodiode according to claim 1 wherein the first layer is an AlAs_{0.56}Sb_{0.44} layer.

11. An avalanche photodiode according to claim 1 wherein the first layer is lattice matched to the substrate and the substrate is Indium Phosphide.

12. An avalanche photodiode according to claim h wherein the second layer comprises an InGaAs absorption layer.

13. An avalanche photodiode according to claim 12 wherein the second layer is lattice matched to the substrate.

14. A method of fabricating an avalanche photodiode comprising:
depositing a first layer comprising Aluminium Arsenide Antimonide over a substrate;
depositing a second layer over the first layer; and
removing a portion of the first layer so that the first layer has a smaller cross-sectional area than the second layer in a plane parallel to the substrate.

15. A method according to claim 14, wherein the removing a portion of the first layer comprises performing a wet oxidation process on the first and second layers.

16. A method according to claim 15 wherein the removing a portion of the first layer further comprises removing oxide formed by the wet oxidation process.

17. A method according to claim 14 wherein prior to the removing a portion of the first layer, an etch process is performed on the first layer and the second layer to form a structure comprising the first layer and the second layer with vertical or near vertical sidewall(s).

18. A method according to claim 14 wherein a dielectric material is deposited on sides of the first layer and second layer.

19. A method according to claim 14 wherein the first layer is deposited using a digital alloy process.
